(19) United States
(12) Patent Application Publication
(10) Pub. No.: US 2003/0117878 A1
(43) Pub. Date: Jun. 26, 2003

(54) Semiconductor memory and method for bit and/or byte write operation

(76) Inventor: Takashi Yamada, Kawasaki (JP)

Correspondence Address: Darryl G. Walker, WALKER & SAKO, LLP, Suite 235, 300 South First Street, San Jose, CA, 95113, US

(21) Appl. No.: 10/329,244

(22) Filed: Dec. 23, 2002

(30) Foreign Application Priority Data
Dec. 25, 2001 (JP) 2001-391559

(51) Int. Cl. G11C 8/00

(52) U.S. Cl. 365/230.03

(57) ABSTRACT

A semiconductor memory is disclosed that may provide bit and/or byte write functionalities with smaller increase in area, reduced power consumption and reduction in design time. According to one embodiment, a semiconductor memory may include a number of banks that each includes memory cell arrays (A00 to Anm), a column selector (C00 to Cnm), a sense amplifier/write driver section (R00 to Rnm), and a data input/output section (I00 to I0n). In a bit (or byte) write mode, an input/output section can disable a write to a bit (or byte) by driving a bit lines to a same potential as a precharge operation, regardless of the fact that a memory cell has been connected to such bit lines by a word line and column selector.

### TECHNICAL FIELD

The present invention relates generally to a semiconductor memory write functions, and more particularly to a semiconductor memory having bit and/or byte write functions and methods therefor.

### BACKGROUND OF THE INVENTION

As is well understood, data can be written to, and read from a semiconductor memory. Many semiconductor memories access data according to a predetermined width. However, it can be desirable to provide a semiconductor memory in which a portion of an accessed data width may be excluded from a write operation. Such a feature is referred to as bit write function, when writes may be excluded on a bit wise basis, and as a byte write function, when writes may be excluded on a byte wise basis.

To better understand various aspects of the present invention, a memory device will be discussed with reference to FIG. 1. FIG. 1 is a block diagram of a static random access memory (SRAM) that can include a bit write function. Thus, writes to the memory device may be enabled or disabled on a bit-by-bit basis. Of course, SRAMs can also be manufactured without a bit write function. Such SRAMs can have the same elements as FIG. 1, except not include inputs for bit write control signals (WEB0 to WEBn).

In FIG. 1, various SRAM sections can be combined to provide circuit blocks directed to an accessed bit. Thus, FIG. 1 shows an input/output (I/O) section (I/O0), memory cell arrays A00, A01 to A0m, sense amplifier/write driver sections R00, R01 to R0m, and column selectors C00, C01 to C0m, which may form a circuit block for a one bit (a 0^{th} bit in this particular case). Such a structure may be repeated for other bits of the SRAM. Accordingly, FIG. 1 shows a circuit block for an nth bit that may include an I/O section (I/On), memory arrays An0, An1 to Anm, sense amplifier/write driver sections Rn0, Rn1 to Rnm, and column selectors Cn0, Cn1 to Cnm.

In FIG. 1, it will be assumed that a memory cell array and associated sense amplifier/write driver section and column selector can form a unit referred to as a “bank.” For example, memory cell array A00, sense amplifier/write driver section R00, and column selector C00 may form a bank BANK0, while memory array Anm, sense amplifier/write driver sections Rnm, and column selector Cnm may form a bank BANKm.

Accordingly, in FIG. 1, because there are 0^{th} through mth banks for each bit, and there are n+1 bits, an SRAM may include a total of (m+1)×(n+1) banks.

In operation, an address signal ADDRESS can be applied to a control signal section CNT. An address signal ADDRESS may include a bank address, a column address, and a row address. Any of banks (BANK0 to BANKm) can be selected according to a bank address. Within each memory cell array (A00 to Anm), memory cells (not shown) may be arranged in a matrix. Within a memory cell array (A00 to Anm), a pair of bit lines (a column line) can be selected by a column address, and a word line (row line) can be selected by a row address. In this way, memory cell at a crossing point of a selected column line and row line can be selected.

Word drivers WORD DRIVER can drive word lines in memory cell arrays (A00 to Anm). In FIG. 1, word drivers can be shared for all accessed data bits, and so are shown collectively on a left side of an SRAM. Conversely, a column selector (C00 to Cnm) can select column lines, and is provided on a bank-by-bank basis. Similarly, a sense amplifier/write driver section (R00 to Rnm) can be provided for each bank.

In addition to an address signal ADDRESS, a control section CNT can also receive an external clock CLK and an external readout/write mode switching signal CWEB. In addition, an SRAM may receive data input signals DI0 to DIn, provide data output signals D00 to D0n, and receive bit write control signals WEB0 to WEBn at I/O sections IO0 to IOn, respectively. As previously noted, if an SRAM does not provide a bit write function, bit write control signals WEB0 to WEBn may be excluded.

Referring now to FIG. 5, a block schematic diagram is set forth illustrating a conventional circuit configuration for an SRAM that does not have a bit (or byte) write function. The particular circuit configuration of FIG. 5 shows circuits corresponding to a kth bit. FIG. 5 shows an I/O section IOk, a sense amplifier/write driver section Rkm, a column selector Ckm, and a memory cell array Akm.

In FIG. 5, during a write operation, a data input signal DIk is received at an input data latch 15. Such an input data value DIk may be driven on common data lines RT and RB by common data line driver 14. In contrast, in a read operation, read data transmitted from common data lines RT and RB can be provided as an output signal DOk through an output latch 12 and output driver 13.

FIG. 5 also shows an internal clock signal CL and internal write enable signal WE. Such signals are generated by a control section, like that shown as CNT in FIG. 1. An internal clock signal CL and internal write enable signal WE can be provided to an I/O section IOk. In particular, an internal clock signal CL, which can be in phase with an external clock signal CLK, can be connected to input data latch 15 and a common data line precharge circuit 11. Internal write enable signal WE can be connected to an inverter 18 and control input of common data line driver 14.

Common data lines RT and RB are also referred to as global bit lines, and may be situated on an SRAM so as to extend across all banks associated with an accessed bit value (e.g., kth bit). Such global bit lines can be connected to each sense amplifier/write driver section for a bit value. Thus, in the example of FIG. 5 it is understood that global bit lines can be connected to sense amplifier/write driver section Rk0 to Rkm. FIG. 5 illustrates a case in which an mth bank is selected, thus common data lines RT and RB are connected to output terminals of a read driver pair 9 and input terminals of a write data receiving inverter pair 7.

In a write operation, write data transmitted by common data lines RT and RB can be received by write data receiving inverter pair 7 which may provide inputs to write driver 4. Write driver 4 may thus transmit data on common data lines RT and RB to common bit lines DTm and DBm. In a read operation, read data on common bit lines DTm and DBm can be amplified by a sense amplifier 6, which may provide inputs to read driver pair 9 by way of inverter pair 8.

Referring still to FIG. 5, a sense amplifier enable signal SEm and an inverted write enable signal WBm, which are provided to a sense amplifier/write driver section Rkm, can be shared for each accessed data bit across multiple banks to thereby read or write data in a multi-bit fashion. Such signals may also be in synchronism with an internal clock signal CL. A sense amplifier enable signal SEm can activate a sense amplifier 6 to start amplifying a received data signal. An inverted write enable signal WBm can activate a write driver 4, and may utilize inverter 5 for such an operation.

Common bit lines DTm and DBm can be connected to one of a number of bit line pairs 2 by a column selector Ckm. Bit line pairs 2 may be local bit line pairs (as opposed to global bit line pairs). In the particular example of FIG. 5, one of eight bit line pairs 2 can be selected according to a column selection signal S[0:7].

Word lines for a memory cell array Akm are shown in FIG. 5 as WL0 to WLx.

Having described the structure of an SRAM that does not include a bit (or byte) write function, the operation of such a structure will now be described with reference to FIGS. 5 and 6. FIG. 6 is a timing diagram showing a response for an internal clock signal CL, an internal write enable signal WE, an inverted write enable signal WBm, word line responses WL, an input data value DIk, a common data line response RT, RB, a common bit line response DTm, DBm, a sense amplifier enable signal SEm, and an output data value DOk. FIG. 6 also shows about two periods of internal clock signal CL, with half periods being distinguished by dashed lines.

In FIG. 6, a first illustrated section can correspond to a write operation while a second illustrated section can correspond to a read operation. A write enable signal WE and inverted write enable signal WBm can be generated from a logical operation between internal clock signal and external readout/write mode switching signal CWEB. However, inverted write enable signal WBm may be further delayed as the generation of such a signal also includes a logical operation with a bank address signal.

Activation of word lines, as represented by responses WL, can also be in synchronism with an internal clock signal CL. Thus, a response WL can rise and fall in synchronism with an internal clock signal CL. In the particular example of FIG. 6, a word line WL0 is activated in a first section to write a data value of “0” into a memory cell, while a word line WL1 is activated in a second section to read a data value of “1” from memory cell.

An input data value DIk may be low in the first part of FIG. 6, illustrating the writing of a data value of “0.”

As noted above, common data lines RT and RB can carry input or output data. A first section of FIG. 6 shows common data lines RT and RB receiving input data DIk in complementary format that can be driven by write driver 4. A second section of FIG. 6 shows common data lines RT and RB receiving complementary output data from sense amplifier 6 for output as data output DOk. It is noted that while common data lines RT and RB may be driven to complementary data values in synchronism with an internal clock signal CL in both a read and write operation, activation of such common data lines RT and RB can occur at a later point in time in a read operation than a write operation.

Common bit lines DTm and DBm can provide data to, or receive data from, a memory cell array. A first section of FIG. 6 shows common bit lines DTm and DBm receiving input write data from write driver 4. A second section of FIG. 6 shows common data lines DTm and DBm receiving a complementary read data output from a memory cell selected from within a memory cell array by column selector Ckm. A memory cell is typically designed to occupy as small an area on a memory device as possible, and thus may have a smaller data driving capabilities than other circuits. Consequently, complementary read output may change more slowly with respect to other transitions, as shown in FIG. 6. Once a potential difference between common bit lines DTm and DBm reaches a value sufficient for a read operation, a sense amplifier enable signal SEm can be activated, as also shown in FIG. 6. In response to an active sense amplifier enable signal SEm, a sense amplifier 6 can cause common data lines RT and RB to be driven according to the data on common bit lines DTm and DBm. A resulting value on common data lines RT and RB can be provided as output data value DOk.

While the various control signals illustrated in FIG. 6 may be activated in synchronism with an internal clock signal, a time lag may occur between transition in an internal clock signal and corresponding transitions in a control signal due to signal propagation delay. For example, if reference is made to FIG. 6, a write enable signal WE transition from low-to-high occurs with a slight delay with respect to a corresponding transition in an internal clock signal CL. Such a delay can arise from write enable signal WE being routed from a control section (e.g., CNT in FIG. 1) to multiple I/O sections (e.g., IO0 to IOn in FIG. 1), thus having to traverse all such I/O sections. For example, in FIG. 1, such a signal propagation delay can be caused by signal travel in a horizontal direction.

An inverted write enable signal WBm may have multiple propagation delay factors. In particular, different inverted write enable signals may be provided to all of multiple sense amplifier/write driver sections (e.g., R00 to Rnm in FIG. 1). Consequently, such signals may suffer from propagation delay introduced by travel in multiple directions in a memory device. For example, in FIG. 1, such a signal propagation delay can be caused by travel in both a horizontal and vertical direction.

In the case of word lines, even greater signal propagation delay can occur, as a row decode operation can be required to select from among multiple word lines (e.g., WL0 to WLx).

Thus, even when a memory device operates in a synchronous fashion, delays between an internal clock signal and corresponding control signals can occur, as such timing signals must be distributed to a large number of different areas and/or objects in a memory device. Such variations in timing are often referred to as “skews.”

Skews can vary according a number of factors, including those associated with manufacturing as well as those associated with operating environment (e.g., power supply voltage and/or temperature). As a result, memory devices are often designed to address timing of a sense amplifier enable signal (e.g., SEm) to ensure the skews in such a signal do not result in an erroneous operation.

Referring now to FIG. 7, a block schematic diagram is set forth illustrating a conventional circuit configuration for an SRAM that includes a bit write function. The particular circuit configuration of FIG. 7 shows circuits that write data to a kth bit. The bit write capable circuit of FIG. 7 may differ from that of FIG. 5 in that a bit write control signal WEBk can be received as an input to an I/O section IOk, and an I/O section IOk may include a bit write latch 19 and a sense amplifier/write driver section RKm can include a delay element 23 and a NAND gate 21. As shown in FIG. 7, a bit write latch 19 can provide an inverted bit write latch output signal BWE. Such an inverted bit write latch output signal BWE can be provided to all banks for one bit. Thus, in the example of FIG. 7, an inverted bit write latch output signal BWE can be provided to each of sense amplifier/write driver sections Rk0, Rk1 . . . to Rkm.

FIG. 7 shows a particular connection for an mth bank Akm. In particular, inverted bit write latch output signal BWE can be connected to one input of NAND gate 21 of sense amplifier/write driver section Rkm. Further, inverted write enable signal WBm can be input to another input of NAND gate 21 through a delay element 23 (which may invert such a signal).

The operation of the SRAM illustrated in FIG. 7 will now be described with reference to FIGS. 7 and 8. FIG. 8 is a timing diagram showing the same general responses as FIG. 6. However, because the SRAM provides a bit write function, FIG. 8 also includes response for a bit write control signal WEBk can and an inverted bit write latch output signal BWE.

FIG. 8 shows two general time periods. A first time period may correspond to a first clock cycle and show a write operation that writes a data value of “0.” A second time period may correspond to a second clock cycle and show a bit write disable operation in which a memory cell is accessed that stores a value “0” while other portions of the SRAM proceed with a write operation. Such an operation can be achieved by disabling a bit write according to a bit write control signal WEBk.

In FIG. 8, a write enable signal WE and inverted write enable signal WBm may function in the same general fashion as described with reference to FIG. 6. However, it is noted that in FIG. 8, such signals are activated in the second time period (those of FIG. 6 are inactive in the corresponding time period).

Word line responses WL and input data value DIk of FIG. 8 can be the same as that shown in FIG. 6.

Because a bit write control signal WEBk is low at the rise of internal clock signal CL in the first time period of FIG. 8, a write operation to a kth bit can be enabled. Such a bit write control signal WEBk can be latched in a bit write latch 19 according to an internal clock signal CL, which can output inverted bit write latch output signal BWE to sense amplifier/write drive section Rkm. Inverted bit write latch output signal BWE may be inverted with respect to bit write control signal WEBk.

Conventionally, within a sense amplifier/write drive section Rkm, write operations may be controlled by logically combining an inverted bit write latch output signal (e.g., BWE) and an inverted write enable signal (e.g., WBm). Thus, a write to a kth bit can be controlled according to both an inverted bit write latch output signal BWE and an inverted write enable signal WBm. Unfortunately, in such a conventional approach, signal skew can lead to erroneous operation. In particular, a skew in an inverted bit write latch output signal (e.g., BWE) with respect to an inverted write enable signal (e.g., WBm) may result in a write driver being erroneously activated following a proper bit write operation.

Thus, an erroneous bit write operation as described above can result from mismatches in timing (also called “racing”). Such timing conflicts can be prevented by employing more precise timing designs. One such approach is shown in FIG. 7, which includes a delay element 23. With a delay element 23, an erroneous write operation can be prevented, despite the fact that a fall in an inverted write enable signal WBm may overlap a high inverted bit write latch output signal BWE at the time an internal clock signal CL is active, as shown in FIG. 8. Of course, the configuration of FIG. 7 is but one example to address timing drawbacks, and other solutions may be pursued by adjusting timing in other ways.

Referring again to FIG. 8, in a second time period, a bit write control signal WEBk can rise, resulting in inverted bit write enable BWE signal falling. Such an operation can switch an SRAM from a bit write enable mode to a bit write disable mode (for the kth bit). Because a write enable signal WE is activated, common data line driver 14 may drive common data lines RT and RB according to a data input value DIk (which is high in the example of FIG. 8). Thus, a response of data lines RT and RB can be the same the first part of FIG. 6.

In the second time period of FIG. 8, because common data lines RT and RB are coupled to output data latch 12, an input data value DIk driven on common data lines RT and RB can be output as an output data value DOk, with a slight delay with respect to a rising edge of internal clock CL.

It is also noted that in a second time period of FIG. 8, sense amplifier enable signal SEm remains inactive (low in this case). Consequently, while a column selector CKm may select a memory cell resulting in data being placed on common bit lines DTm and DBm, a sense amplifier 6 remains disabled, preventing such an accessed data value from being driven on common data lines RT and RB.

Because common bit lines DTm and DBm transmit write data to a selected memory cell in a first time period of FIG. 8, a common bit line response DTm, DBm of such a first time period can be the same as the first time period of FIG. 6. However, in the case of FIG. 8 (an SRAM with a bit write function), the activation of a write driver 4 may be delayed to avoid racing at the inputs of NAND gate 21. As a result, low transitions in a common bit line responses DTm, DBm may occur with a slight delay as compared to similar transitions of FIG. 6.

In a second time period of FIG. 8, because word lines (e.g., WL0 and WL1) can extend over all bits (i.e., 0th bit to nth bit), a memory cell can be accessed by the activation of word line WL1. As result, as noted above, common bit lines DTm and DBm may develop a differential voltage.

Referring now to FIG. 9, another a block schematic diagram is set forth illustrating another conventional circuit configuration for an SRAM that includes a bit write function. In the arrangement of FIG. 9, when a bit write is disabled for a kth bit, a data Value for such a bit may be read. The bit write capable circuit of FIG. 9 may differ from that of FIG. 7 in that an I/O section 10k may include a NAND gate 17 having an output that activates common data line drivers 14. A NAND gate 17 may have one input that receives an internal write enable signal WE and another input that receives an inverted bit write latch output signal BWE. In such an arrangement, when a bit write control signal WEBk transitions high, ending a bit write function, a resulting low inverted bit write latch output signal BWE can disable common data line driver 14, thereby preventing input data DIk from being driven on common data lines RT and RB.

The operation of the SRAM illustrated in FIG. 9 will now be described with reference to FIGS. 9 and 10. FIG. 1O is a timing diagram showing the same general responses as FIG. 8. However, because the SRAM of FIG. 9 provides a bit read function for those bits having disabled bit write functions, in a second time period data may be read from a kth bit while data may be being written to other bits.

FIG. 10 may differ from FIG. 8 in that a sense amplifier enable signals SEm may be activated (driven high in this example) in a second time period. Accordingly, in a second time period of FIG. 10, a internal clock signal CL may initially be low, resulting in precharge circuit 11 precharging common data line RT and RB to a high value. When inverted bit write latch output signal BWE is low, common data line driver 14 can be in a high impedance state. When internal clock signal CL transitions high, precharge circuit 11 can be disabled. Sense amplifier signal SEm may then be activated, and sense amplifier 6, by way of inverter pair 8 and read driver pair 9, may drive common data lines RT and RB according to data provided to common bit lines DTm and DBm. Such a data value may be latched in output data latch 12 and provided as an output data value DOk.

Referring now to FIG. 11, a block schematic diagram is set forth illustrating conventional circuit configuration for an SRAM that includes a byte write function. FIG. 11 includes a left side portion, corresponding to a kth bit, and a right side portion, corresponding to a (k+1)th bit. A left side portion may have the same general configuration as FIG. 9. Sense amplifier and data output circuitry can be the same as those shown in FIGS. 5, 7 or 9, and so are excluded from FIG. 11.

Thus, like FIG. 9, in FIG. 11 when an internal write enable signal WE is active (high in this example) and a byte write control signal BWBk is active (low in this example), data may be written to a kth bit. Similarly, if a byte write control signal BWBk is inactive, a write to a kth bit can be disabled.

However, unlike the above described bit write arrangements, in the byte write example of FIG. 11, writes may be enabled or disabled in a byte-wise fashion. To accomplish such byte operations, FIG. 11 includes a left side portion with a NAND gate 17 that generates a common data line driver control signal 25 shared by all bits of a same byte. Thus, a common data line driver control signal 25 can control not only common data line driver 14 for a kth bit, but also common data line driver 24 for a (k+1)th bit. In this way, one byte write control signal BWBk can control writes to a byte (e.g., eight or nine bits).

A response for an SRAM with a byte write function like that shown in FIG. 11 can be similar to that of FIG. 10, it being understood that write operations may be enabled and disabled in a byte-wise fashion.

FIG. 12 corresponds to a FIG. 1 of Japanese Patent 2598424 B (JP 2598424 B), and shows transfer gates TG11 to TGm4. Transfer gates (TG11 to TGm4) can be added at the input terminals of memory cells MC11 to MCm4, respectively. Such transfer gates can enable a bit write function. It is noted that while the various examples of FIGS. 5, 7, 9 and 11 are assumed to be on-chip SRAMs having a customized design, the SRAM disclosed in JP 2598424 B is formed using basic logic cells, such as gate arrays. Therefore, memory cells (MC11 to MCm4) of JP 2598424 B are configured as conventional latches, or similar circuits, rather than well-known memory cells configurations, such as six transistor (6-T) SRAM cell, as can be the case for FIGS. 5, 7, 9 and 11.

The difference in memory cells of the SRAM of JP 2598424 B, as compared to SRAMs like that of FIGS. 5, 7, 9 and 11 is shown by differences in signals and signal connections. As will be recalled, in a typical SRAM (e.g., like those that can include 6-T type memory cells), data can be read or written via a same pair of bit lines by selecting one word line. Such a pair of bit lines can carry complementary data. In contrast, in the example of FIG. 12, data may be written to a memory cell (MC11 to MCm4) via a write data line (e.g., Dw1) but may be read from such a memory cell by read data line (e.g., Dr1) that is different from a write data line. Still further, the memory cells (MC11 to MCm4) of JP 2598424 B operate in response to four word lines, as opposed to one. In particular, data on write data line Dw1 can be written to a memory cell MC11 by selecting word lines Ww11 and Ww12. Similarly, read data for memory cell MC11 can be read on read data line Dr1 by selecting word lines Wr11 and Wr12. Thus, JP 2598424 B differs in memory cell structure by including different data lines for read data and write data, and four word lines: two for write operations and two for read operations.

The bit write control mechanism of JP 2598424 B also differs greatly from that of FIGS. 5, 7, 9 and 11. As will be recalled, in FIGS. 5, 7, 9 and 11 bit writes can be controlled by enabling or disabling write driver circuits in a bit-wise fashion. In contrast, in JP 2598424 B, erroneous bit writes are prevented by turning off a transfer gate (TG11 to TGm4) at data input sections of memory cells (MC11 to MCm4).

Conventional techniques for simplifying a write control system include those disclosed in Japanese Laid-Open Applications 6-44780 (JP 6-44780) and 8-249884 (JP 8-249884). The former reference (JP 6-44780) discloses a dynamic RAM (DRAM) in which a writing area is reduced to further higher levels of integration. The reference JP 6-44780 particularly discloses a DRAM with first write circuits (FIG. 4 of JP 6-44780) and second write circuits (FIG. 3 of JP 6-44780). A first write circuit (WDV) may receive a first control signal (/MFLGn) and a data from an input buffer as input signals, and can have a first data line (e.g., /D1_n) as an output. A second write circuit (e.g., FIG. 3) can receive a second control signal (/WGT) and the first data line (e.g., /D1_n) as inputs, and can have a second data line (e.g., /D2_n) as an output. In JP 6-44780, a first write circuit (WDV) can place a first data line in a pre-defined state according to a first control signal (/MFLGn). A second write circuit (e.g., FIG. 3) can enter a predetermined state in response to the first data line being in the predefined state, regardless of the value of the second control signal (/WGT).

The latter reference (JP 8-249884) is aimed at reducing a device pattern area by using a write data bus and data bus in a shared fashion. The reference JP 8-249884 discloses a write per bit circuit for a semiconductor memory in which a switch circuit (e.g., 61) can be turned off or on based on logical states of a pair of data lines (e.g., DB₁, *DB₁). Thus, a state of a switch circuit (e.g., on or off) determines whether or not data is written into a memory cell.

Thus, various conventional SRAMs are known that include bit write or byte write functions. Such conventional approaches may have drawbacks, however, when compared with SRAMs that do not have such capabilities.

First, in the conventional SRAM examples of FIGS. 7, 9 and 11, a bit write function is accomplished by adding circuitry not only to I/O sections (e.g., n+1 I/O sections), but also to sense amplifier/write driver sections Rkm (e.g., (n+1)×(m+1) sense amplifier/write driver sections). Thus, adding a bit write function translates into a cost increase, as such circuits can increase chip area considerably, as circuitry must be added to each bank of a device. Further, because a bit write enable signal (e.g., BWE) is provided to all banks (e.g., m+1 banks) associated with a same bit, area must be reserved for such a wiring.

In the case of the conventional SRAM shown in FIG. 12 (JP 2598424 B), a bit write function is achieved by adding at least a transfer gate to each memory cell. Such an approach has great impact on the area of a resulting SRAM device, as the number of memory cells is obviously much greater than the number of banks. While JP 2598424 B states that there is no increase in circuit area for such an approach, it is understood that such a statement is in regard to gate array arrangements, and not to typical customized SRAM designs (e.g., like those that include 6-T type cells).

Another drawback to conventional SRAM, like those of FIGS. 7, 9 and 11, can be power consumption. In the conventional SRAMs of FIGS. 7, 9 and 11, a relatively large number of bit (or byte) write enable signals BWE must be charged and discharged. As will be recalled, a wiring for a BWE signal may be routed through all banks for a given bit (or byte), and hence include a substantial capacitance that is charged and discharged. Further, in cases where a delay element 23 is included to address timing conflicts (racing), such delay elements 23 can also contribute to increased power consumption. In particular, delay elements 23 can often include multiple logic gate stages having large gate lengths that are interconnected to provide accurate delay amounts. The charging and discharging of such large gate size transistors can add substantially to power consumption. Thus, achieving accurate timing in such delay elements 23 may require that a certain amount of power be consumed.

An approach like that of FIG. 12 may also consume considerable power. As will be recalled in the case of FIG. 12, bit write operations can include activating a write data line (e.g., Dw1, Dw2 . . . ) that can be connected to a number of transfer gates in addition to the transfer gate of the memory cell being accessed. For example, if memory cell MC11 is accessed for a bit write operation, in addition to transfer gate TG11, write data line Dw1 may also turn on transfer gates TG21, TG31 . . . TGm1. Thus, because write data lines (e.g., Dw1, Dw2 . . . ) are connected to a large number of transfer gates, the activation and de-activation of such lines can result in considerable power consumption.

Another drawback to conventional SRAM, like those of FIGS. 7, 9 and 11, can be complexity in design. As previously noted, racing between timing for signals received by sense amplifier/write driver sections (Rkm) must be accounted for in order to ensure proper operation. Further, sense amplifier/write driver sections (Rkm) are provided on a bank-by-bank basis. Consequently, such timing signals will fan out in a two dimensional expanse: in a direction parallel to a word line and a direction parallel to bit line pairs. As a result, timing signals for sense amplifier/write driver sections (Rkm) may vary due to delay in two directions, and may also vary in order of arrival. Addressing such timing complexities can add to overall design time for an SRAM device. Such complex timing arrangements are in sharp contrast to a timing of signals for I/O sections (IOk), for example. Conflicts in timing for signals arriving at I/O sections (IOk) are relatively easy to address, as I/O sections (IOk) can be arranged side-by-side in a single direction (as opposed to a two dimensional matrix like arrangement for sense amplifier/write driver sections).

Drawbacks to the approach of JP 6-44780 may include circuit size and power consumption. As will be recalled, JP 6-44780 shows a second write circuit (FIG. 3) that may use input data (D1_n and /D1_n) and a control signal /WGT to place an output in a high impedance state, and thereby deactivate the write circuit. Assuming a complementary metal-oxide-transistor (CMOS) design, a second write circuit may include 16 transistors, resulting in a complicated circuit. Such a complicated circuit can disadvantageously consume a relatively large area on a device, and also consume considerable power.

A drawback to the approaches of both JP 6-44780 and JP-249884 A can be that logical operations are carried out near write amplification circuits. Thus, complexities in timing may arise, as described above, if such conventional SRAMs included multiple banks arranged in more than one direction.

In light of the above, it would be desirable to provide a semiconductor memory having a bit write and/or byte write function that may not result in the same increase in device area as conventional approaches like those described above.

It would also be desirable to provide a semiconductor memory having a bit write and/or byte write function that may consume less power when the bit write or byte write function is disabled, as compared to conventional approaches like those described above.

Still further, it would also be desirable to provide a semiconductor memory having a bit write and/or byte write function that may present less complicated signal timing, and thus shorten design time, as compared to conventional approaches like those described above.

### SUMMARY OF THE INVENTION

According to one embodiment, a semiconductor memory can include a number of circuit blocks, each associated with at least one access bit of a plurality of access bits. Each circuit block can include a memory cell array having a plurality of memory cells selectable by word lines and bit lines, a sense amplifier/write driver section, and a column selector that selects at least one bit line pair according to a column address. The semiconductor memory can also include an input/output (I/O) section associated with each of the plurality of access bits. In a write disable mode, each I/O section can drive both lines of a bit line pair selected by the column address to the same potential.

According to one aspect of the embodiments, a same potential for a pair of bit lines in a write disable mode can be a precharge potential to which bit lines are precharged prior to a data access operation.

According to another aspect of the embodiments, a write disable mode can be a bit write disable mode that disables a data write to the access bit associated with the I/O section.

According to another aspect of the embodiments, a write disable mode can be a byte write disable mode that disables a data write to a predetermined set of access bits that includes the access bit associated with the I/O section.

According to another aspect of the embodiments, a semiconductor memory can be further arranged into a number of banks. Each bank can be selectable by a bank address, and may include at least one memory cell array, column selector and sense amplifier/write driver section.

According to another aspect of the embodiments, each sense amplifier/write driver section of a semiconductor memory may include a write driver. A write driver can drive both lines of a bit line pair selected by a column address to a same potential in a write disable mode, and with complementary data values in a write enable mode.

According to another aspect of the embodiments, each I/O section of a semiconductor memory can be connected to at least one sense amplifier/write driver section by a pair of common data lines. Each I/O section may also include a common data line driver for transmitting data values on the pair of common data lines, a precharge circuit for precharging a pair of common data lines to a same precharge potential, and a disable control circuit that inactivates the common data line driver and activates the precharge circuit at the same time.

According to another aspect of the embodiments, a disable control circuit of an I/O section can inactivate a common data line driver and activates a precharge circuit in response to a disable signal.

According to another aspect of the embodiments, a sense amplifier/write driver section can include a write driver that is not controlled by a bit write enable signal.

According to another aspect of the embodiments, sense amplifier/write driver section can include a write driver that is enabled when a write to the associated access bit is enabled, and enabled when a write to the associated access bit is disabled.

The present invention may also include a method of selectively writing bit data to a semiconductor memory device. A method may include in a write enable mode, driving a bit line pair selected according to at least a portion of a memory address with complementary data values, and in a write disable mode, driving both lines of a bit line pair selected according to at least a portion of a memory address to a same potential.

According to one aspect of the embodiments, a method may also include selecting a bit line pair according to at least a portion of a memory address, and coupling a memory cell to the selected bit line pair by a word line activated in response to a memory address.

According to another aspect of the embodiments, a method may further include driving one bit line of a selected bit line pair toward a first potential with a write driver circuit while, at the same time, driving the one bit line toward a second potential different than the first potential with a selected memory cell.

According to another aspect of the embodiments, a method may also include, in both a write enable mode and write disable mode, connecting a bit line pair to a data line pair with a column selector. The method may further include, in a precharge mode, driving both lines of a data line pair to a same potential.

According to another aspect of the embodiments, driving a bit line pair selected according to at least a portion of a memory address to complementary data values can include activating a write driver circuit. Further, driving both lines of a bit line pair to a same potential can include activating a write driver circuit at the same time as a precharge circuit.

The present invention may also include a semiconductor memory having a plurality of memory cells selectable according to memory addresses and a plurality of input/output (I/O) sections. Each I/O section can be associated with a data line pair. Further, each I/O section can drive both lines of an associated data line pair to a same potential while a memory cell is coupled to the data line pair in response to an inactive bit write enable signal.

According to one aspect of the embodiments, a semiconductor memory may also include a plurality of sense amplifier/write driver sections corresponding to each I/O section. Each sense amplifier/write driver section can couple a data line pair associated with a corresponding I/O section to a memory cell with a write amplifier that is activated when a corresponding bit write enable signal is inactive.

According to another aspect of the embodiments, a semiconductor memory may also include a plurality of column selectors corresponding to each I/O section. Each column selector can couple a data line pair to a bit line pair that is connected to a memory cell.

According to another aspect of the embodiments, each I/O section of a semiconductor memory can include a precharge circuit coupled to an associated data line pair. At least one of the I/O sections can include a control circuit that activates a precharge circuit in response to an inactive bit write enable signal.

According to another aspect of the embodiments, a control circuit of at least one I/O section can activate precharge circuits for a plurality of I/O sections. In addition, a bit write enable signal can correspond to a plurality of access bits.

### BRIEF DESCRIPTION OF THE DRAWINGS

FIG. 1 is a block diagram of a static random access memory (SRAM) having a bit write function.

FIG. 2 is a block schematic diagram of a circuit configuration for a kth bit of an SRAM according to a first embodiment of the present invention.

FIG. 3 is a timing diagram showing the operation of the SRAM of FIG. 2.

FIG. 4 is a block schematic diagram of a circuit configuration for a kth bit of an SRAM according to a second embodiment of the present invention.

FIG. 5 is a block schematic diagram of a conventional circuit configuration for a kth bit of an SRAM that does not include a bit write function.

FIG. 6 is a timing diagram showing the operation of the conventional SRAM of FIG. 5.

FIG. 7 is a block schematic diagram of a conventional circuit configuration for a kth bit of an SRAM that includes a bit write function.

FIG. 8 is a timing diagram showing the operation of the conventional SRAM of FIG. 7.

FIG. 9 is a block schematic diagram of another conventional circuit configuration for a kth bit of an SRAM that includes a bit write function.

FIG. 10 is a timing diagram showing the operation of the conventional SRAM of FIG. 9.

FIG. 11 is a block schematic diagram of a conventional circuit configuration for an SRAM that includes a byte write function.

FIG. 12 is a diagram that corresponds to FIG. 1 of Japanese Patent 2598424 B (JP 2598424 B).

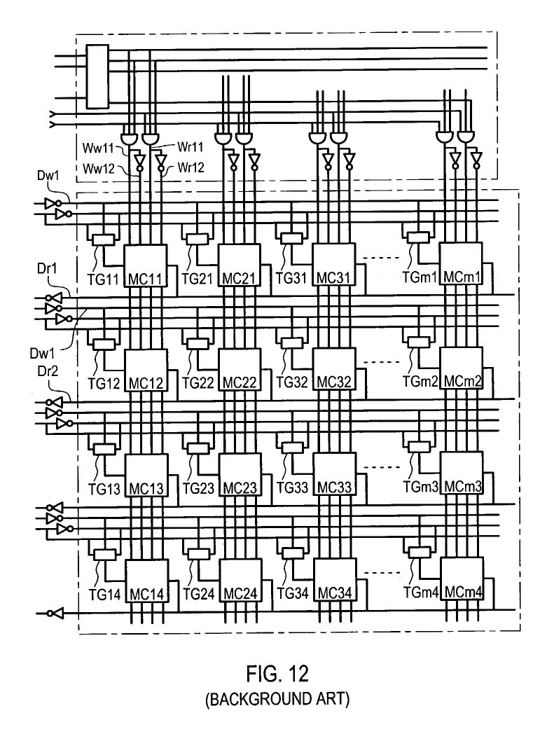

### DETAILED DESCRIPTION OF THE EMBODIMENTS

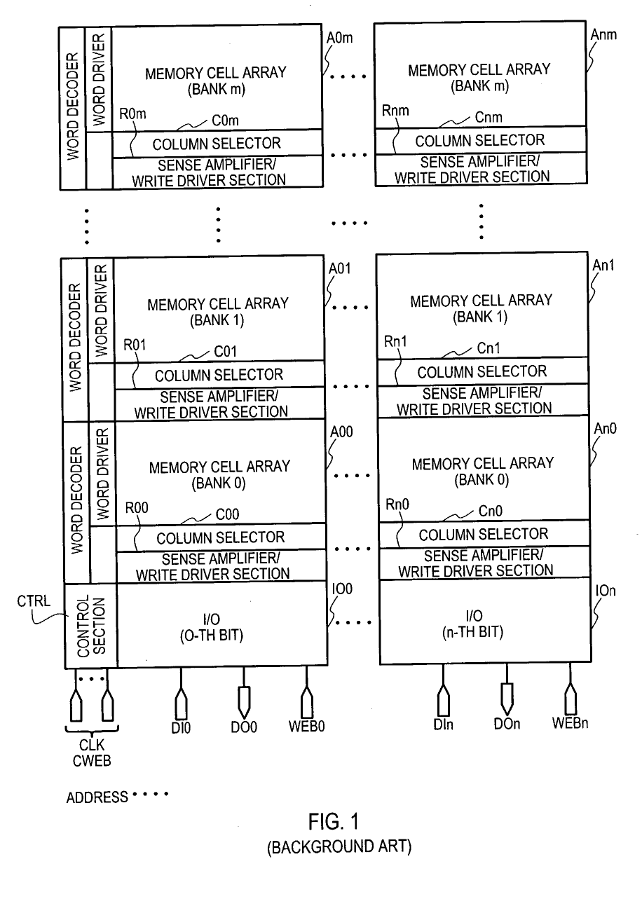

Various embodiments of the present invention will now be described in detail with reference to a number of drawings. The embodiments can include a static random access memory (SRAM) that can have the same general layout and provide a bit write function according to the same general input signals as the SRAM set forth in FIG. 1. Accordingly, a general block arrangement of an SRAM according to an embodiment can be the same as FIG. 1, and thus a detailed description of such will be omitted.

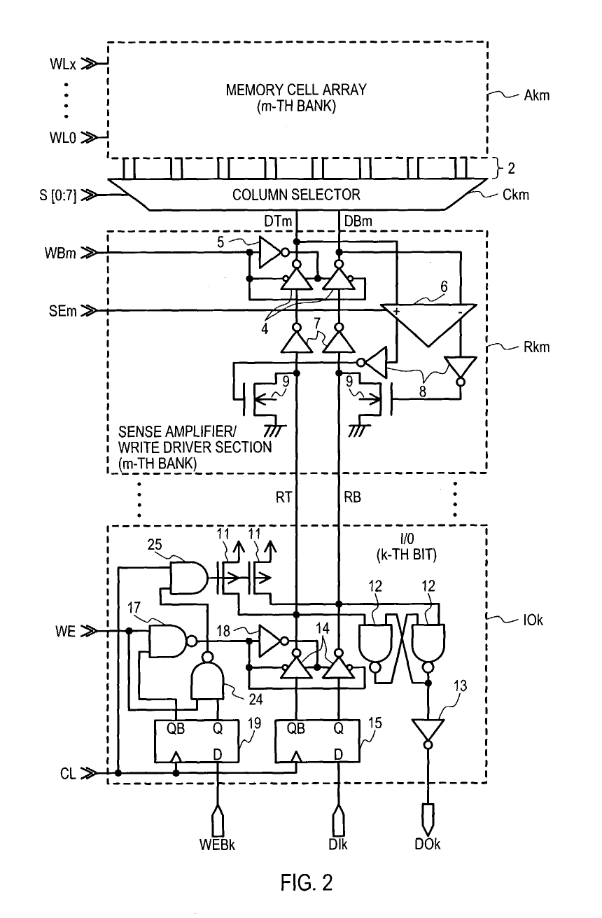

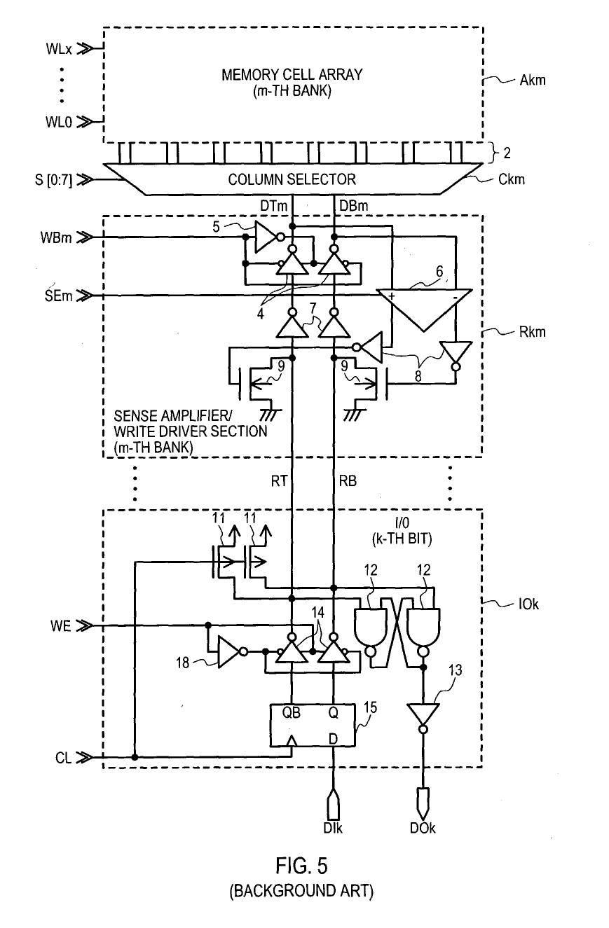

Referring now to FIG. 2, a block schematic diagram is set forth illustrating a circuit configuration according to one embodiment that can corresponding to a kth bit of an SRAM. The circuit of FIG. 2 may be similar to that of FIG. 5, but may have an I/O section IOk having a different configuration. Therefore, an mth bank AKm, column selector Ckm, and sense amplifier/write driver section Rkm, can be essentially the same as those of FIG. 5, thus a detailed description of such sections will be omitted.

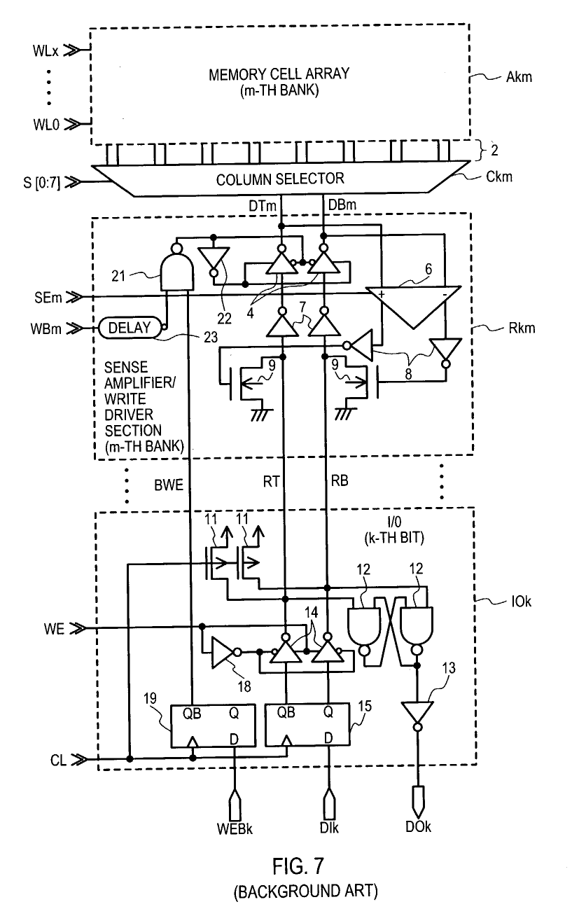

An I/O section IOk according to FIG. 2 may include an output data latch 12, an output driver 13, a data input latch 15, a common data line driver 14, common data lines RT and RB, and a bit write control signal latch 19. An I/O section IOk may also provide a data output signal DOk, and receive a data input signal DIk, an internal clock signal CL, a write enable signal WE, and a bit write control signal WEBk. These features can be essentially the same as corresponding items of the conventional circuit shown in FIG. 7.

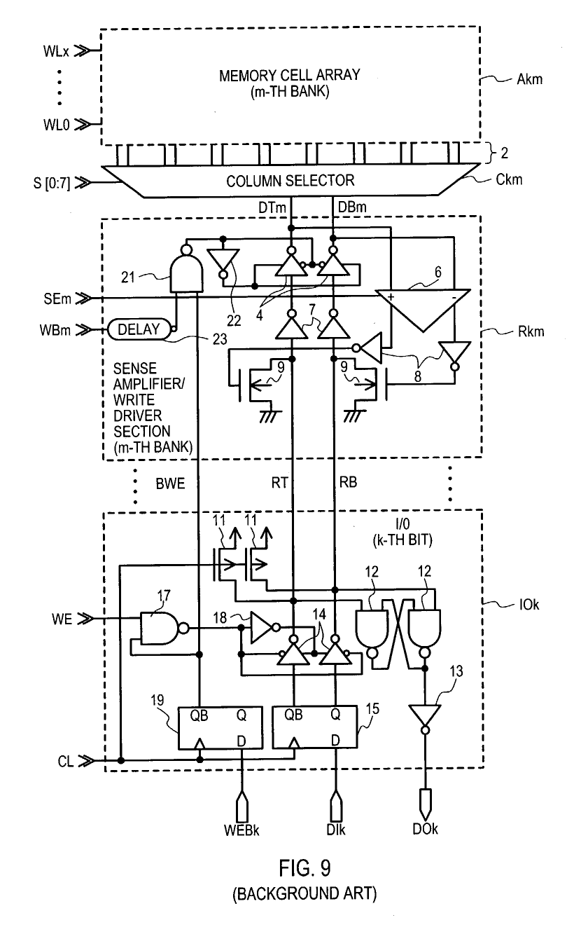

An I/O section IOk according to FIG. 2 may also include a NAND gate 17. Such a NAND gate can control a common data line driver 14 in the same general way as corresponding items in the conventional circuit shown in FIG. 9.

In addition to including a bit write control signal latch 19 and NAND gate 17, an I/O section according to FIG. 2 can further differ from FIG. 5. In the embodiment of FIG. 2, a bit write control signal WEBk can be received by a bit write control signal latch 19, and thus can be similar to the conventional example of FIGS. 7 and 9. Further, a NAND gate 17 may receive an inverting output of a bit write control signal latch 19 as one input and a write enable signal WE as another input, as in the case of FIG. 9.

However, unlike the various conventional approaches, the I/O section 10k of FIG. 2 can include a NAND gate 24. A NAND gate 24 can receive an internal write enable signal WE as one input, and a non-inverting output of a bit write control signal latch 19 as another output. An output of NAND gate 24 can be provided to an input of an AND gate 25.

In addition to receiving an output of NAND gate 24 as one input, AND gate 25 may also receive an internal clock signal CL as an input. An output of AND gate 25 can control a common data line precharge circuit 11. In particular, a common data line precharge circuit 11 may include two p-channel transistors having gates commonly connected to an output of AND gate 25.

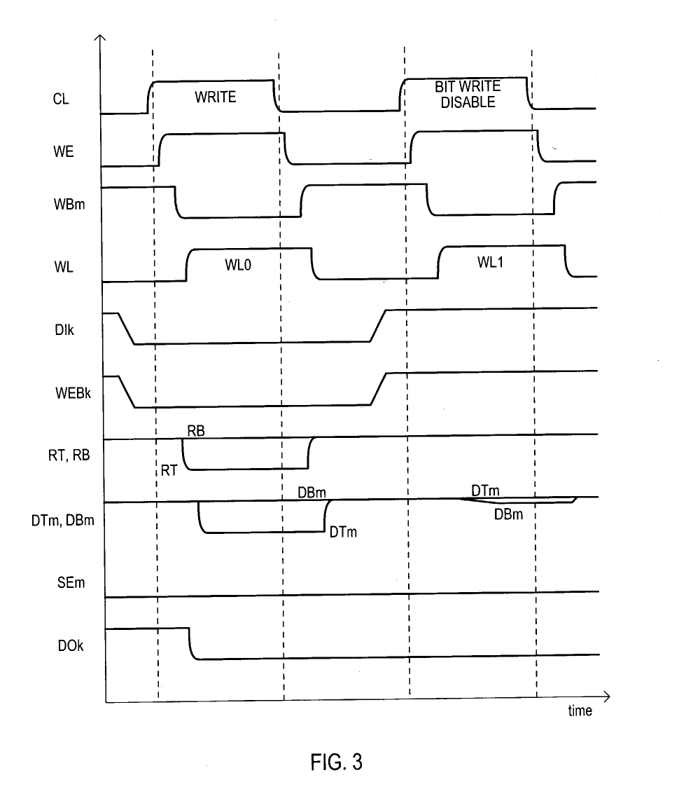

Having described the various features of the embodiment of FIG. 2, the operation of the embodiment of FIG. 2 will now be described with reference to FIGS. 2 and 3. FIG. 3 is a timing diagram showing a response for an internal clock signal CL, an internal write enable signal WE, an inverted write enable signal WBm, word line responses WL, an input data value DIk, a bit write control signal WEBk, a common data line response RT, RB, a common bit line response DTm, DBm, a sense amplifier enable signal SEm, and an output data value DOk.

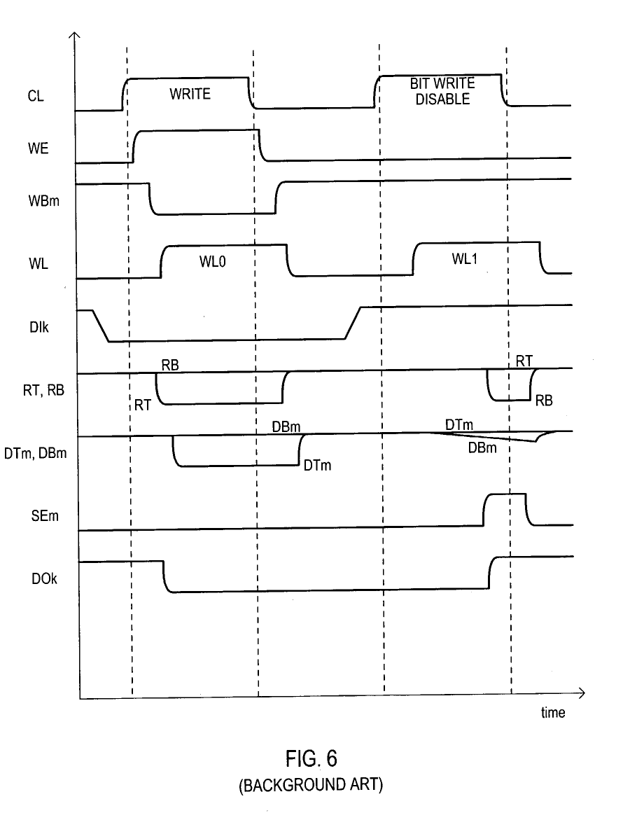

FIG. 3 also shows about two periods of internal clock signal CL, with half periods being distinguished by dashed lines. In FIG. 3, a first illustrated time period can correspond to a write operation while a second illustrated time period can correspond to a bit write disable operation. A write operation of FIG. 3 can be essentially the same as FIG. 6 (with the addition that a bit write control signal WEBk can be low). Thus, a description of such an operation will be omitted.

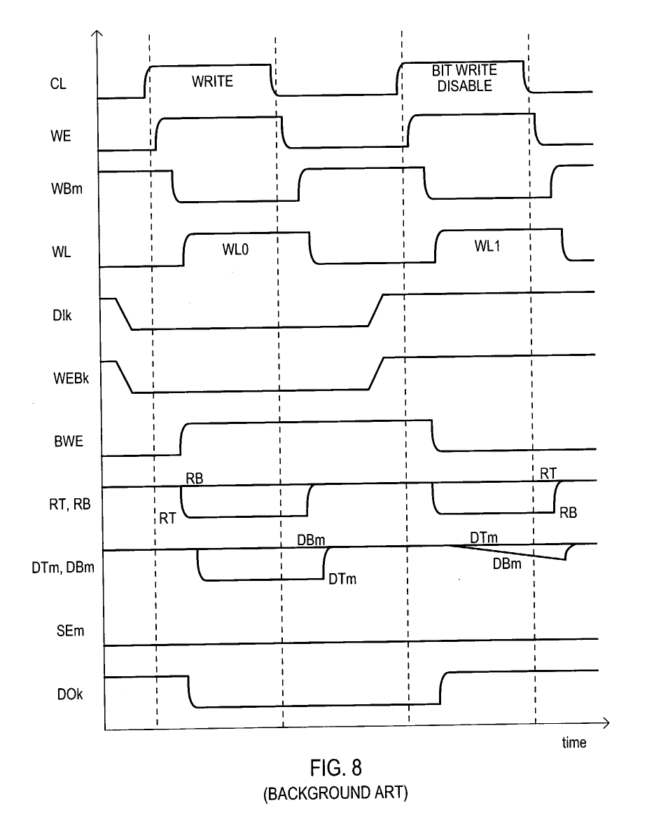

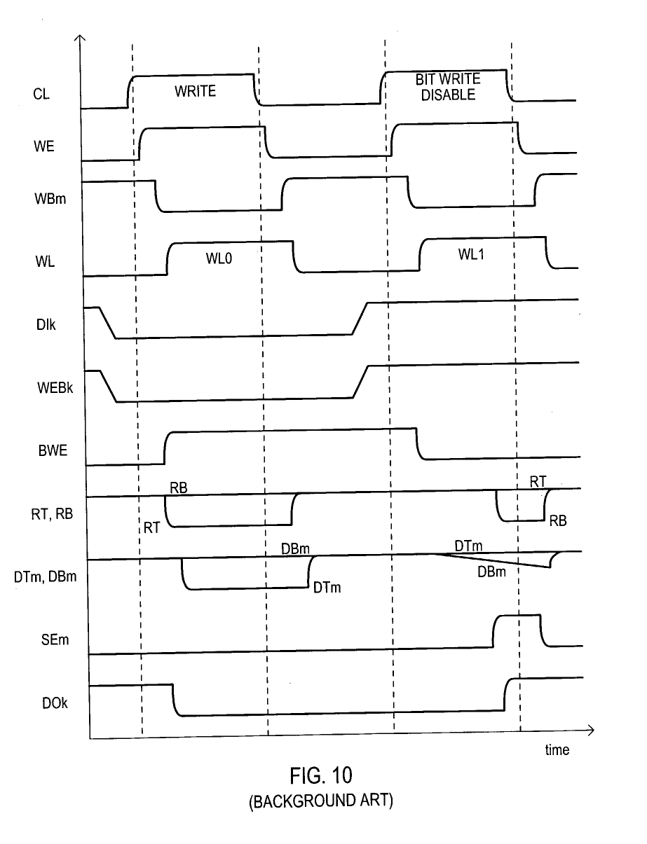

The second illustrated time period of FIG. 3 can be similar to the bit write disable operation shown in the second section of FIG. 10. However, the operation of FIG. 3 can differ from that of FIG. 10 in a number of ways. First, a sense amplifier enable signal SEm is not activated (e.g., does not rise), and a sense amplifier 6 does not operate. Thus, FIG. 3 shows a result like that of FIG. 8, and hence a read function, like that of FIG. 10 is not necessarily a function provided by the embodiment of FIG. 2.

A second difference between the bit write disable operations of FIG. 3 and FIG. 10 is that a common data line precharge circuit 11 can operate whether an internal clock signal CL is high or low, provided an internal write enable signal WE is active (high) and a bit write control signal WEBk is inactive (high). In contrast, in the conventional examples described, a common data line precharge circuit 11 is always activated when an internal clock signal CL is low, and is always de-activated when the internal clock signal CL is high. In such conventional arrangements, when a common data line precharge circuit 11 is activated, a memory device can be considered to be in a precharge mode. Thus, unlike conventional cases, in an SRAM according to the embodiment of FIG. 2, in a bit write disable operation (WEBk high and CL high), a common data line precharge circuit 11 and a common data line driver 14 may continue to operate in the same general manner as a precharge mode, even if an internal clock signal is high (i.e., precharge circuit 11: active, driverl4: inactive).

A third difference between the bit write disable operations of FIG. 3 and FIG. 10 is that in a bit write disable operation, a write driver 4 can operate in the same fashion as a normal write operation. In the embodiment of FIGS. 2 and 3, in a bit write disable operation, an inverted write enable signal WBm can be low, thus a write driver 4 can be activated. However, because common data lines RT and RB can both be high in a bit write disable operation, a write driver 4 can drive both of common bit lines DTm and DBm to a high level. However, in the same operation a memory cell can be selected by activation of a word line WL1 and operation of column selector Ckm, as in the case of a read operation. Consequently, at the same time a write driver 4 is driving common bit lines DTm and DBm to a high level, a selected memory cell can be driving one of common bit lines (e.g., DBm) toward a low level. This can cause a “through” current to flow.

Using FIG. 2 as an example, assuming that a common bit line DBm is being driven toward a low level, a through current path could include write driver 4, common bit line DBm, column selector Ckm, a bit line 2, and a storage terminal on a selected memory cell that can reach ground. Thus, while such a through current is flowing, a potential of a “low” common bit line DBm can be decreased to a potential determined by a resistance ratio of such a current path, and may not be a logic low level.

While the generation of through currents is typically avoided in order keep power consumption levels low, a through current like that generated in the above described embodiments may not significantly contribute to overall power consumption. Because a write driver 4 operates in the above, embodiment, a “low” side common bit line DBm can be kept at a potential higher than in a read operation. Further, due to such potential levels, the power necessary to precharge a bit line pair 2 and common bit line pair DTm and DBm in a subsequent precharge operation can be smaller. In this way, increased power due to a through current may be offset by reductions in power consumption provided by the embodiments.

Additional power savings may arise from an arrangement like that of FIGS. 2 and 3. As noted above and shown in FIG. 3, there can be no change in the potentials at common data lines RT and RB when the SRAM according to the present invention enters a bit write disable mode. Thus, unlike conventional approaches, essentially no power is consumed in charging and discharging common data lines RT and RB and/or gates of p-channel transistors that form common data line precharge circuit 11. Still further, essentially no power is consumed by output data latch 12 and output driver 13, as no change in data value occurs. Even further, within sense amplifier/write driver section Rkm, data values input to inverter pair 7 do not change state, thus inverter pair 7 consumes essentially no additional power. It is noted that inverter pairs 7 can exist in each write driver section (e.g., Rk0 to Rkm) of the associated kth bit. In this way, power consumption in an SRAM as a whole may be smaller in a write and read operation, as compared to conventional approaches.

Further, with common data lines RT and RB at a same potential as at precharge, write driver 4 does not have to drive common bit line pair DTm and DBm to different values.

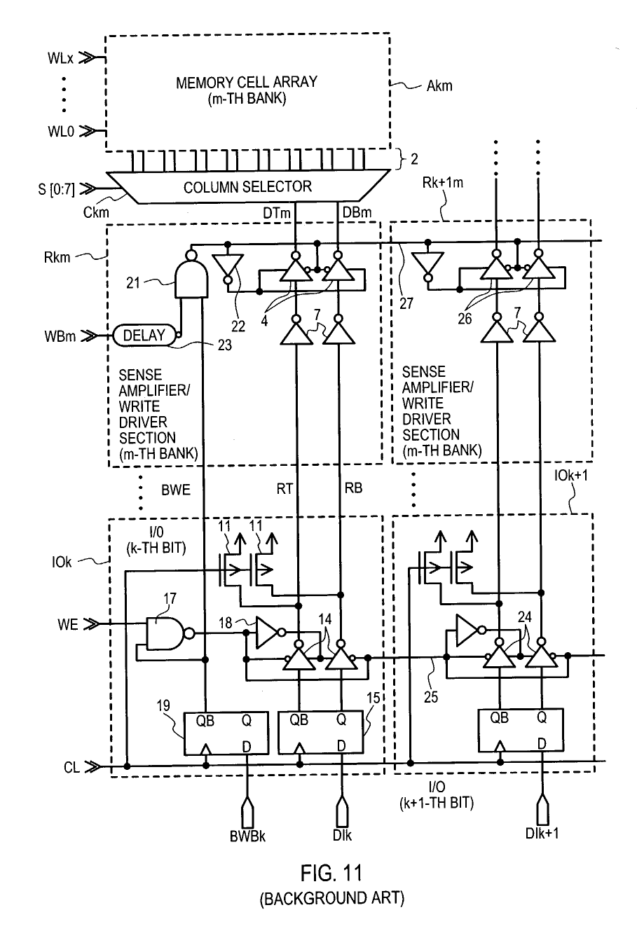

Even more power savings may be achieved in the embodiment of FIGS. 2 and 3, as such an embodiment may not include a bit write control signal (shown as BWE in FIGS. 7 to 11), which can be indispensable in such conventional approaches. This is because in the disclosed embodiment, a status of bit write control signal WEBk need not be transferred to a write driver 4. Because a bit write control signal can be excluded in the above embodiments, a wiring for such a signal can be eliminated, conserving power that might otherwise be necessary to drive such wiring between logic levels.

The elimination of the need for bit write control signals (BWE) in the present invention may also lead to savings in circuit area. As will be recalled, conventional approaches may include a bit write control signal BWE wiring that extends from an I/O section to each sense amplifier/write driver section for the associated bit (e.g., kth bit). Thus, elimination of such a wiring frees up area, allowing such area to be used for other purposes, or eliminated for overall smaller size.

It is further noted that because the embodiments do not control a write driver 4 on a bit-by-bit basis, a sense amplifier/write driver circuit Rkm according to the present invention can have simpler timing requirements. Thus, it may not be necessary to redesign a control circuit for a write driver to readjust timing, as occurs in the above described conventional approaches. As a result, it may be possible reduce the amount of time to design a bit and/or byte write SRAM as compared with conventional approaches.

The disclosed embodiment can also vary considerably from previously described conventional approaches disclosed in JP 6-44780 and JP 8-249884, in that a write gate for masked data does not destroy memory cell data. Such a result can be achieved in the embodiments by driving complementary inputs to a write gate to the same potential as that which occurs in a precharge operation. The disclosed invention specifically differs from the approaches of JP 6-44780 and JP 8-249884 in that there is no need for a logical operation between input data to a write gate and a write gate control signal to disable a write for a specific bit. That is, the disclosed invention does not have to include a logic circuit that can determine when input data to a write circuit is to be ignored, and alternatives to ignoring data are not included. Thus, the disclosed invention may include fewer circuit elements than the above conventional approaches. Accordingly, an SRAM according to the present invention can be more advantageous in terms of area required and/or power consumed.

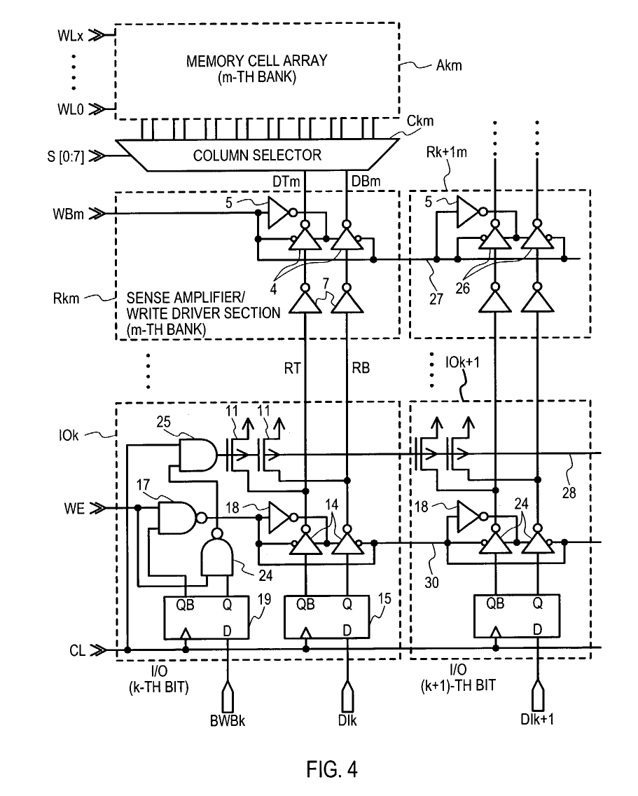

Referring now to FIG. 4, a block schematic diagram is set forth illustrating another embodiment of the present invention in which a bit write system like that illustrated in FIG. 2 can be applied to an SRAM having a byte write function. Sense amplifier and data output circuitry can be the same as that shown in FIG. 2, and so are excluded from FIG. 4.

FIG. 4 includes a left side portion, corresponding to a kth bit, and a right side portion, corresponding to a (k+1)th bit. A left side portion may have the same general configuration as FIG. 2, except that a byte write control signal BWBk can be input, instead of a bit write control signal WEBk. Accordingly, a detailed description of such a portion will be omitted.

A right side portion, which may represent a (k+1)th bit and remaining bits in an accessed word may differ considerably from conventional approaches. As can be seen in FIG. 4, control signals generated in an I/O section 10k may be utilized by a right side portion. Thus, an I/O section IOk can generate a common data line driver control signal 30, a common data line precharge control signal 28, and a write driver control signal 27, all of which may be shared with a right side portion.

In this way an SRAM can be provided with a byte write function by providing a byte write control signal BWB every eight or nine bits (e.g., every byte), to thereby control writes to the bits of such bytes in a collective fashion. Of course, while the disclosed embodiments have described a “byte” as including eight or nine bits, the present invention is not limited to such particular byte sizes.

As has been described above in detail, approaches to providing bit and/or byte write functions to a semiconductor memory have been disclosed that may have minimal or essentially no increase in area as compared to a semiconductor memory without such a function. Such approaches can include eliminating the need to control a write driver according to bit (or byte) write criteria.

Further, according to the disclosed embodiments, power consumption can be reduced when a bit write is disabled (i.e., a write is prevented to a particular bit). Power for charging wiring capacitance can be significantly reduced as a state of a bit write control signal (e.g., WEBk) does not have to be transferred to numerous write driver circuits for a given bit. In addition or alternatively, in a bit write disable operation, data values provided to a write driver can be same as in a precharge operation.

Further, according to the disclosed embodiments, a design time may be reduced for a semiconductor memory having a bit and/or byte write function. Such an advantage may be achieved because a write driver operation need not be controlled according to a state of a bit write control signal (e.g., WEBk). Thus, control circuits for write drivers need not be redesigned to meet complex timing requirements of conventional approaches. In particular, the timing for outputting write data from a write driver section may not have to be readjusted, and thus can reduce memory design time.

Accordingly, from the above it is understood that the present invention can achieve a bit write operation (an operation that can control data writes to individual bits or bytes) that may be particular suitable for SRAMs having multi-bank configurations. Bit (or byte) writes may be controlled in a similar fashion as conventional approaches.

However, in a conventional approach, if a bit write to a memory cell is not disabled, a data value within the memory cell can be destroyed (e.g., overwritten). Such a situation arises because a conventional semiconductor memory with a bit (or byte) write function can include (1) a control circuit to disable a write driver during a bit write disable, where such a control circuit has an adjusted timing to avoid race conditions, and (2) a bit write control signal that is input to an I/O section, but transmitted to a write driver in order to disable such a write driver. The need to transmit such bit write control signals over various portions of a semiconductor memory can lead to increased area requirements, increased design time, and/or increased power consumption.

In sharp contrast, according the present invention, a semiconductor memory can include (1) a control circuit for a write driver that can be similar to a semiconductor memory without a bit write function; (2) a write driver that functions in the same manner during a bit write disable operation as a bit write operation; (3) in a bit write disable operation, a write driver is supplied with input values that do not result in the destruction of data in an accessed memory cell, instead of being supplied with normal input data; and (4) input values to a write driver are generated according to a bit write control signal provided to an I/O section, with bit write control signals not being provided to a write driver.

Such an advantageous design can result in a semiconductor memory with bit (or byte) write functionality having reduced area, lower power consumption, and/or a shorter design time than conventional approaches.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor memory, comprising:
a plurality of circuit blocks, each associated with at least one access bit of a plurality of access bits, each circuit block including,
a memory cell array having a plurality of memory cells selectable by word lines and bit lines,
a sense amplifier/write driver section, and
a column selector that selects at least one bit line pair according to a column address; and
an input/output (I/O) section associated with each of the plurality of access bits, in a write disable mode, each I/O section driving both lines of a bit line pair selected by the column address to a same potential.

2. The semiconductor memory claim 1, wherein:
the same potential is a precharge potential to which bit lines are precharged prior to a data access operation.

3. The semiconductor memory of claim 1, wherein:
the write disable mode is a bit write disable mode that disables a data write to the access bit associated with the I/O section.

4. The semiconductor memory of claim 1, wherein:
the write disable mode is a byte write disable mode that disables a data write to a predetermined set of access bits that includes the access bit associated with the I/O section.

5. The semiconductor memory of claim 1, wherein:
the semiconductor memory is further arranged into a plurality of banks, each selectable by a bank address, each bank including at least one memory cell array, column selector and sense amplifier/write driver section.

6. The semiconductor memory of claim 1, wherein:
each sense amplifier/write driver section includes a write driver that drives both lines of the bit line pair selected by the column address to the same potential in a write disable mode, and drives the bit line pair with complementary data values in a write enable mode.

7. The semiconductor memory of claim 1, wherein:
each I/O section is connected to at least one sense amplifier/write driver section by a pair of common data lines and includes
a common data line driver for transmitting data values on the pair of common data lines,
a precharge circuit for precharging the pair of common data lines to a same precharge potential, and
a disable control circuit that inactivates the common data line driver and activates the precharge circuit at the same time.

8. The semiconductor memory of claim 7, wherein:
the disable control circuit inactivates the common data line driver and activates the precharge circuit in response to a disable signal.

9. The semiconductor memory of claim 1, wherein:
the sense amplifier/write driver section includes a write driver that is not controlled by a bit write enable signal.

10. The semiconductor memory of claim 8, wherein:
the sense amplifier/write driver section includes a write driver that is enabled when a write to the associated access bit is enabled, and enabled when a write to the associated access bit is disabled.

11. A method of selectively writing bit data to a semiconductor memory device, comprising the steps of:
in a write enable mode, driving a bit line pair selected according to at least a portion of a memory address with complementary data values; and
in a write disable mode, driving both lines of a bit line pair selected according to at least a portion of a memory address to a same potential.

12. The method of claim 11, further including:
selecting the bit line pair according to at least a portion of a memory address; and
coupling a memory cell to the selected bit line pair by a word line activated in response to the memory address.

13. The method of claim 11, further including:
driving one bit line of the selected bit line pair toward a first potential with a write driver circuit, and at the same time, driving the one bit line toward a second potential different than the first potential with a selected memory cell.

14. The method of claim 11, further including:
in both the write enable mode and write disable mode, connecting the bit line pair to a data line pair with a column selector; and
in a precharge mode, driving both lines of the data line pair to the same potential.

15. The method of claim 11, wherein:
the step of driving the bit line pair selected according to at least a portion of a memory address to complementary data values includes activating a write driver circuit; and
the step of driving both lines of the bit line pair to the same potential includes activating the write driver circuit at the same time as a precharge circuit.

16. A semiconductor memory, comprising:
a plurality of memory cells selectable according to memory addresses; and
a plurality of input/output (I/O) sections, each associated with a data line pair, each I/O section driving both lines of the associated data line pair to the same potential while a memory cell is coupled to the data line pair in response to an inactive bit write enable signal.

17. The semiconductor memory of claim 16, further including:
a plurality of sense amplifier/write driver sections corresponding to each I/O section, each sense amplifier/write driver section coupling the data line pair associated with the corresponding 1/0 section to the memory cell with a write amplifier that is activated when a corresponding bit write enable signal is inactive.

18. The semiconductor memory of claim 16, further including:
a plurality of column selectors corresponding to each I/O section, each column selector coupling the data line pair to a bit line pair that is connected to the memory cell.

19. The semiconductor memory of claim 16, wherein:
each I/O section includes a precharge circuit coupled to the associated data line pair, and
at least one of the I/O sections includes a control circuit that activates the precharge circuit in response to an inactive bit write enable signal.

20. The semiconductor memory of claim 19, wherein:
the control circuit activates precharge circuits for a plurality of I/O sections; and
the bit write enable signal corresponds to a plurality of access bits.
